(19) United States
(12) Patent Application Publication
(10) Pub. No.: US 2016/0072015 A1
(43) Pub. Date: Mar. 10, 2016

(54) VERTICAL ULTRAVIOLET LIGHT EMITTING DEVICE AND METHOD FOR MANUFACTURING THE SAME

(71) Applicant: Seoul Viosys Co., Ltd., Ansan-si (KR)

(72) Inventors: Jung Hwan Hwang, Ansan-si (KR); Chang Suk Han, Ansan-si (KR); Chang Geun Jang, Ansan-si (KR); Hwa Mok Kim, Ansan-si (KR)

(21) Appl. No.: 14/846,592

(22) Filed: Sep. 4, 2015

Related U.S. Application Data
(60) Provisional application No. 62/046,005, filed on Sep. 4, 2014.

(51) Int. Cl. H01L 33/30; H01L 33/00; H01L 33/60; H01L 33/58; H01L 33/06; H01L 33/62

(52) U.S. Cl. CPC H01L 33/305; H01L 33/06; H01L 33/62; H01L 33/60; H01L 33/58; H01L 33/0075; H01L 2933/0033; H01L 2933/0058; H01L 2933/0066

(57) ABSTRACT

Disclosed herein are a vertical ultraviolet light emitting device including: a p-type semiconductor layer including Al; an active layer positioned on the p-type semiconductor layer and including the Al; an n-type semiconductor layer positioned on the active layer and including the Al; a metal contact layer positioned on the n-type semiconductor layer and doped with an n type; and a pad formed on the metal contact layer, wherein the metal contact layer has an Al content lower than that of the n-type semiconductor layer, and a method for manufacturing the same. According to the exemplary embodiments of the present invention, the metal contact layer is formed on the n-type semiconductor layer to allow the metal contact layer instead of the n-type semiconductor layer including AlGaN to act as the contact layer, thereby effectively improving the n type contact characteristics of the vertical ultraviolet light emitting device.

### CROSS-REFERENCE TO RELATED APPLICATIONS

This application claims priority from and the benefits of U.S. Provisional Application No. 62/046,005 entitled “VERTICAL ULTRAVIOLET LIGHT EMITTING DEVICE AND METHOD THEREOF” and filed on Sep. 4, 2014, the disclosure of which is incorporated by reference as part of the specification of this document.

### TECHNICAL FIELD

This patent document relates to a vertical ultraviolet light emitting device and a method for manufacturing the same. Some implementations of the disclosed technology relate to a vertical ultraviolet light emitting device and a method for manufacturing the same capable of emitting ultraviolet light and improving ohmic contact resistance characteristics.

### BACKGROUND

A light emitting device is an inorganic semiconductor device emitting light by a recombination of electrons and holes. Recently, the light emitting device has been variously used in a display apparatus, a vehicle lamp, general lighting apparatuses, optical communication equipments, etc. Among those, the ultraviolet light emitting device emitting ultraviolet rays may be used for UV curing, UV sterilization, or the like to be used in medical fields, equipment components, etc., and may also be used as a source for making a white light source. As such, the ultraviolet light emitting device may be variously used and applications thereof have been more expanded.

### SUMMARY

This patent document provides an ultraviolet light emitting device and a method for manufacturing the same. Some implementations of the disclosed technology can address problems including a light quantity reduction and electrical characteristics degradation, which may occur from a contact layer due to an increase in Al content at the time of manufacturing an ultraviolet light emitting device.

According to an exemplary embodiment of the disclosed technology, there is provided a vertical ultraviolet light emitting device, including: a p-type semiconductor layer including Al; an active layer positioned over the p-type semiconductor layer and including Al; an n-type semiconductor layer positioned over the active layer and including Al; a metal contact layer positioned over the n-type semiconductor layer and doped with an n type dopant; and a pad formed over the metal contact layer and being contact with the metal contact layer, wherein the metal contact layer has an Al content lower than or equal to that of the n-type semiconductor layer.

In some implementations, the Al content of the metal contact layer decreases in a direction from the n-type semiconductor layer toward the pad. In some implementations, the metal contact layer contacts with the pad at least a portion of the metal contact layer that is free of Alr. In some implementations, the active layer has multi-quantum well structure having quantum barrier layers and a quantum barrier layer closest to the n-type semiconductor layer has a band gap wider than that of other quantum barrier layers.

In some implementations, the metal contact layer has a surface with roughness, and the pad is formed on the surface with roughness.

In some implementations, the metal contact layer may be formed over a portion of the n-type semiconductor layer. In some implementations, the vertical ultraviolet light emitting device may further include: a reflecting layer interposed between the metal contact layer and the n-type semiconductor layer.

In some implementations, the reflecting layer may include a super-lattice layer including layers having different refractive indexes. In some implementations, the reflecting layer includes a single layer having a refractive index lower than those of adjacent layers.

In another aspect, a method of manufacturing a vertical ultraviolet light emitting device is provided. The method may include: forming a metal contact layer doped with an n type dopant over a substrate; forming an n-type semiconductor layer including Al over the metal contact layer; forming an active layer including Al over the n-type semiconductor layer; forming a p-type semiconductor layer including Al over the active layer; separating the substrate from the metal contact layer; and forming a pad over a surface of the metal contact layer from which the substrate is separated.

In some implementations, the method may further include, before the forming the pad: wet-etching a surface of the metal contact layer to form roughness, wherein the pad may be formed over the surface with roughness.

In some implementations, the method may further include, after the forming the pad: wet-etching the surface of the metal contact layer to form roughness.

In some implementations, the method may further include: wet-etching a portion of the surface of the metal contact layer to form roughness, wherein the pad may be formed in the remaining portion without roughness.

In some implementations, the method may further include: forming a reflecting layer between the metal contact layer and the n-type semiconductor layer. In some implementations, the forming the reflecting layer includes forming the reflecting layer with a distributed Bragg reflector (DBR) structure. In some implementations, the forming the reflecting layer includes forming a single layer having a refractive index lower than that of adjacent layers.

In another aspect, a vertical ultraviolet light emitting device is provided to comprise: an epitaxial layer including a p-type semiconductor layer, an n-type semiconductor layer, and an active layer disposed between the p-type semiconductor layer and the n-type semiconductor layer; a metal contact layer formed over the epitaxial layer and having a varying Al content; and a pad formed over the metal contact layer and contacting with the metal contact layer, wherein the metal contact layer has relatively high Al content at a portion close to the epitaxial layer and relatively low Al content at another portion close to the pad.

In some implementations, the Al content increases in a direction from the pad to the epitaxial layer. In some implementations, the metal contact layer is free of Al at a portion in contact with the pad. In some implementations, the active layer has multi-quantum well structure having quantum barrier layers and a quantum barrier layer closest to the n-type semiconductor layer has a band gap wider than that of other quantum barrier layers.

### BRIEF DESCRIPTION OF THE DRAWINGS

FIGS. 1 to 3 are cross-sectional views for describing a method for manufacturing an ultraviolet light emitting device according to a first exemplary embodiment of the disclosed technology.

FIG. 4 is a cross-sectional view illustrating the ultraviolet light emitting device according to the first exemplary embodiment of the disclosed technology.

FIG. 5 is a cross-sectional view illustrating an ultraviolet light emitting device according to a second exemplary embodiment of the disclosed technology.

FIG. 6 is a cross-sectional view illustrating an ultraviolet light emitting device according to a third exemplary embodiment of the disclosed technology.

### DETAILED DESCRIPTION

Like a general light emitting device, the ultraviolet light emitting device has an active layer positioned between an n-type semiconductor layer and a p-type semiconductor layer. In this case, the ultraviolet light emitting device emits light (generally, peak wavelength of 400 nm or less) having a relatively shorter peak wavelength. For this reason, at the time of manufacturing the ultraviolet light emitting device using a nitride semiconductor, if band gap energy of n-type and p-type nitride semiconductor layer is smaller than ultraviolet light energy, the phenomenon that the ultraviolet light emitted from the active layer is absorbed into the n-type and p-type nitride semiconductor layers may occur. As a result, luminous efficiency of the ultraviolet light emitting device is very degraded.

To prevent the reduction of the luminous efficiency of the ultraviolet light emitting device, Al of about 20% or more is contained in the active layer and the nitride semiconductor layer to which the ultraviolet light is emitted. In the case of GaN, the band gap absorbs a wavelength of about 280 nm or more at about 3.4 eV, and therefore GaN essentially includes Al. Generally, at the time of manufacturing the ultraviolet light emitting device of 340 nm or less using the nitride semiconductor, AlGaN having Al of 20% or more is used.

However, when the band gap is increased by increasing the Al content to stop ultraviolet rays from being absorbed into the semiconductor layer, an energy level of a valence band is lowered and thus a work function is increased, such that the side effect that ohmic contact resistance is increased may occur.

In particular, the shorter the wavelength, the higher the Al content. As the Al content is increased, the ohmic contact resistance may be increased and thus a light quantity of the ultraviolet light emitting device may be reduced and a driving voltage of the ultraviolet light emitting device may be increased, which may act as a factor of reducing wall plug efficiency.

Further, in the case of manufacturing the vertical light emitting device, when a sapphire substrate is removed to expose the n-type semiconductor and then n electrodes are contacted, the n electrodes do not contact a Ga face but contact an N face in consideration of crystal structure characteristics of the semiconductor. Therefore, a tunneling effect is reduced and the ohmic contact resistance is more increased. In the case of a visible light emitting device, the above-mentioned problems are insignificant, but if the Al content is increased, the ohmic contact resistance is very high, such that the wall plug efficiency may be remarkably reduced.

Exemplary embodiments of the disclosed technology will be described in more detail with reference to the accompanying drawings.

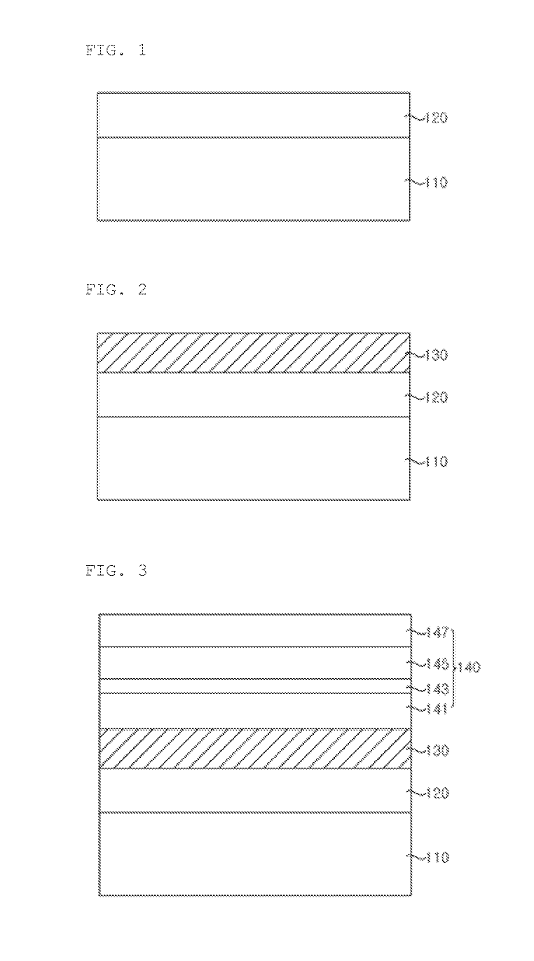

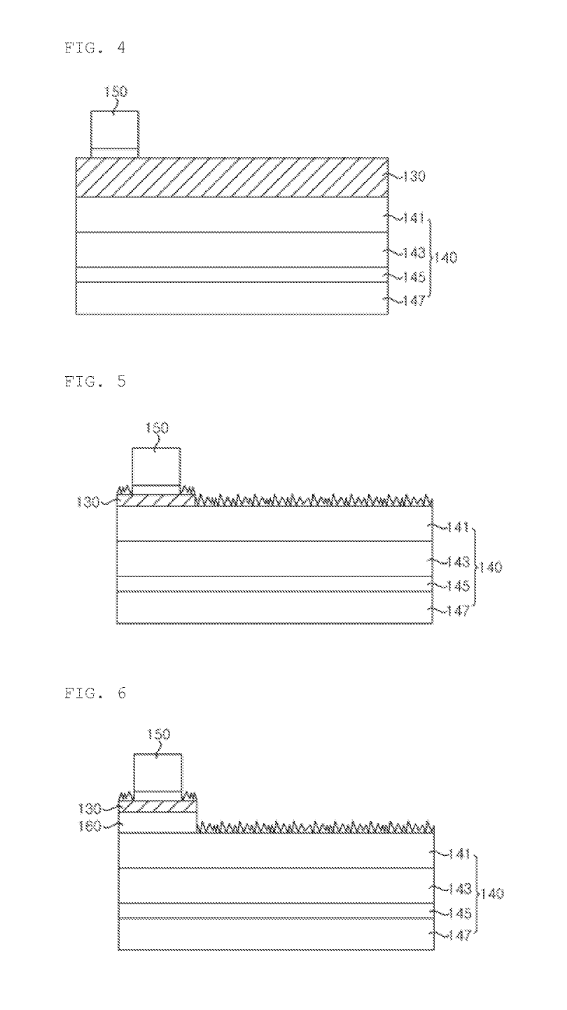

FIGS. 1 to 3 are cross-sectional views for describing a method for manufacturing an ultraviolet light emitting device according to a first exemplary embodiment of the disclosed technology and FIG. 4 is a cross-sectional view illustrating an ultraviolet light emitting device according to a first exemplary embodiment of the disclosed technology. The nitride semiconductor layers to be described may be formed by various methods. For example, the nitride semiconductor layers may be formed by metal organic chemical vapor deposition (MOCVD), molecular beam epitaxy (MBE), or hydride vapor phase epitaxy (HVPE), or the like.

Referring to FIG. 1, a buffer layer 120 may be formed on a substrate 110. The substrate 110 is to grow a nitride semiconductor layer and may be of include a sapphire substrate, a silicon carbide substrate, a spinel substrate, a GaN substrate, or an AlN substrate, etc. The substrate 110 used in the first exemplary embodiment of the disclosed technology may be or include the sapphire substrate and the AlN substrate.

The buffer layer 120 may be grown at a thickness of about 500 nm on the substrate 110. The buffer layer 120 may be or include a nitride layer including (Al, Ga, ln)N. In some implementations, AlN has a large band gap and therefore rarely absorbs a laser, such that AlN may include GaN for laser lift off. Next, the buffer layer 120 may serve as a nuclear layer for growing the nitride layers in the following process and may also serve to relieve a lattice mismatch between the substrate 110 and the nitride layers grown on the buffer layer 120. Further, if necessary, for example, when the substrate 110 is or includes the nitride substrate such as the GaN substrate and the AlN substrate, the buffer layer 120 may be omitted.

Further, as illustrated in FIG. 2, a metal contact layer 130 may be formed on the buffer layer 120. The metal contact layer 130 may be formed to have a thickness of 50 nm to 2 μm and may be doped with an N type. Further, according to the first exemplary embodiment of the disclosed technology, the metal contact layer 130 may be manufactured in the state containing Al. As such, Al may be contained in the metal contact layer 130 to reduce defects or absorption of ultraviolet light which may occur between the substrate 110 and the semiconductor layer including AlGaN.

According to the first exemplary embodiment of the disclosed technology, when Al is contained in the metal contact layer 130, the Al is not uniformly contained in the whole metal contact layer 130 and the metal contact layer 130 may have increasing Al content toward the upper portion in FIG. 2. For example, the metal contact layer 130 may be formed to include a plurality of layers having the increasing Al content toward the upper portion. In some implementations, at least one layer of the metal contact layer 130 may have the Al content stepwise changing so that Al content gradually increases toward the upper portion.

When the Al content of the metal contact layer 130 is gradually increased, a region having the maximum Al content may contact an n-type semiconductor layer and a region having the minimum Al content may contact a pad 150. Further, the Al content of the region contacting the pad 150 becomes 0% and thus the metal contact layer 130 may be formed of or including GaN or InGaN. The Al content of the region contacting the n-type semiconductor layer 141 may be lower than or equal to that of the n-type semiconductor layer 141.

Referring to FIG. 3, the n-type semiconductor layer 141 may be formed on the metal contact layer 130. The n-type semiconductor layer 141 may be grown to have a thickness of about 600 nm to 3 μm using the technologies such as MOCVD. The n-type semiconductor layer 141 may include AlGaN and may include n-type impurities such as Si.

Further, the n-type semiconductor layer 141 may include intermediate insertion layers having different composition ratio. By this configuration, a potential density may be reduced and thus a crystalline structure can be improved.

Further, a super-lattice layer 143 is formed on the n-type semiconductor layer 141. The super-lattice layer 143 may include a multi layer in which layers having different Al concentrations of AlGaN are alternately stacked and may further include AlN. Further, the super-lattice layer 143 may also be formed in a structure in which the AlN layer and the AlGaN layer are repeatedly stacked.

An active layer 145 and a p-type semiconductor layer 147 are sequentially formed on the super-lattice layer 143 to form an epitaxial layer 140. The active layer 145 emits light having predetermined energy by a recombination of electrons and holes. Further, the active layer 145 may have a single quantum well structure or a multi-quantum well structure in which quantum barrier layers and quantum well layers are alternately stacked. Further, the quantum barrier layer close to the n-type semiconductor layer among the quantum barrier layers may have the Al content higher than that of other quantum barrier layers. The quantum barrier layer closest to the n-type semiconductor layer 141 is formed to have the band gap wider than that of other quantum barrier layers to reduce a moving speed of electrons, thereby effectively preventing electrons from overflowing.

The p-type semiconductor layer 147 may be formed by the technologies such as the MOCVD and may be grown to have a thickness of 50 nm to 300 nm. The p-type semiconductor layer 147 may include AlGaN and the composition ratio of Al may be determined to have the band gap energy which is equal to or more than the band gap energy of the well layer within the active layer 145.

FIG. 4 is a diagram illustrating the semiconductor layer after the substrate 110 is removed after the semiconductor layer is grown as described above. FIG. 4 illustrates the upside down the semiconductor layer illustrated in FIG. 3.

After the substrate 110 is separated, the buffer layer 120 is removed by the dry etch or the wet etch. As illustrated in FIG. 4, the metal contact layer 130 may remain without being etched. Alternatively, the metal contact layer 130 goes through the wet dry, such that it may be formed to have a rough surface which is formed in a hexagonal pyramid shape along a crystal surface. A pad 150 is deposited on a surface of the metal contact layer 130 which remains without being etched or on the metal contact layer 130 formed to have the rough surface by PEC etching. Therefore, the pad 150 contacts the metal contact layer 130.

Further, a contact metal (not illustrated) may be formed between the pad 150 and the metal contact layer 130. The contact metal may include any one of An, Ni, ITO, Al, W, Ti, or Cr or two or more of the materials above. When the contact metal includes the two or more of the materials, the materials can be multi-stacked.

Here, the metal contact layer 130 may be formed of or include GaN or n-GaN, but is formed to have the Al content gradually increasing toward the n-type semiconductor layer 141. As described above, the metal contact layer 130 may be formed continuously or stepwise or formed as the super-lattice layer. Further, the Al content contained in the metal contact layer 130 may be formed to be smaller than that of the n-type semiconductor layer 141 and may decrease in a direction from the n-type semiconductor layer 141 toward the pad 150. In this case, the Al content of the metal contact layer 130 may change stepwise.

Since Al is gradually decreased from the n-type semiconductor layer 141 toward the top of the metal contact layer 130, when the metal contact layer 130 contacts the pad 150, the contact portion of the metal contact layer includes GaN or n-GaN and does not contain the Al.

The pad 150 may be formed to contact a portion or the whole of the metal contact layer 130. As described above, the Al content of the region in which the metal contact layer 130 contacts the pad 150 may be reduced to effectively improve N-type contact characteristics. Further, as a lattice constant of the metal contact layer 130 is slowly reduced toward the n-type semiconductor layer 141 having a high Al content, a stress occurring between the substrate 110 and the n-type semiconductor layer 141 can be effectively relieved.

As a result, Al is contained to effectively improve electrical characteristics.

FIG. 5 is a cross-sectional view illustrating an ultraviolet light emitting device according to a second exemplary embodiment of the disclosed technology.

Referring to FIG. 5, like the first exemplary embodiment of the disclosed technology, in the ultraviolet light emitting device according to the second exemplary embodiment of the disclosed technology, the substrate 110 is separated, the buffer layer 120 is removed by the dry etch or the wet etch, and the pad 150 is deposited on the metal contact layer 130. As such, the metal contact layer 130 of a portion where the pad 150 is not formed goes through the wet etch in the state in which the pad 150 is deposited on the metal contact layer 130.

As described above, among the metal contact layers 130, the region in which the pad 150 is not formed is removed by the wet etch, such that the metal contact layer 130 may minimize the absorption of ultraviolet light.

FIG. 6 is a cross-sectional view illustrating an ultraviolet light emitting device according to a third exemplary embodiment of the present invention.

Referring to FIG. 6, in the ultraviolet light emitting device according to the third exemplary embodiment of the present invention, a reflecting layer 160 may be formed between the metal contact layer 130 and the n-type semiconductor layer 141 and may include AN or AlGaN. In this state, the substrate 110 is separated, the buffer layer 120 is removed by the dry etch or the wet etch, and then the metal contact layer 130 of the region in which the pad 150 is not formed is etched. In this case, the reflecting layer 160 may be etched while the metal contact layer 130 is etched. After the metal contact layer 130 and the reflecting layer 160 are etched, the contact metal (not illustrated) is deposited on the metal contact layer 130 and the pad 150 is deposited thereon.

As described above, even though the metal contact layer 130 and the reflecting layer 160 are etched, the metal contact layer 130 and the reflecting layer 160 remain under the pad 150. Therefore, the ultraviolet light generated from the active layer 145 is not absorbed into the metal contact layer 130 due to the reflecting layer 160 but is reflected from the metal contact layer 130, thereby increasing the light efficiency of the ultraviolet light emitting device according to the exemplary embodiment of the disclosed technology.

In this case, the reflecting layer 160 may be formed of an AlN single layer. The AlN layer has a refractive index smaller than that of the n-AlGaN of the n-type semiconductor layer 141, such that the ultraviolet light satisfying total reflection conditions among the ultraviolet light generated from the active layer 145 may be reflected. To this end, the thickness of the AlN layer may be formed at 1 nm to 200 nm and may be formed at a thickness which is equal to or more than a half wavelength of the ultraviolet light. That is, the single AlN layer may have a thickness enough to reflect the ultraviolet light generated from the active layer 145.

Further, the reflecting layer 160 may be formed by alternately stacking semiconductor layers having different reflective indexes. A thickness of each layer may be formed at a thickness of 1 nm to 200 nm and may be formed at an integer multiple of the half wavelength of the ultraviolet light. The super-lattice layer forms a disturbed Bragg reflector (DBR), thereby remarkably improving reflectivity.

As set forth above, according to the exemplary embodiments of the disclosed technology, the metal contact layer is formed on the n-type semiconductor layer to allow the metal contact layer instead of the n-type semiconductor layer including AlGaN to act as the contact layer, thereby effectively improving the n-type contact characteristics of the vertical ultraviolet light emitting device.

Further, the metal contact layer goes through the dry or wet etch to prevent the light absorption from occurring in the metal contact layer in advance, thereby maximizing the light extraction efficiency of the vertical ultraviolet light emitting device.

Although the detailed description of the disclosed technology is made with reference to the accompanying drawings, the foregoing exemplary embodiments are provide to facilitate understanding some examples of the disclosed technology and therefore the disclosed technology is not limited to the exemplary embodiments. The scope of the disclosed technology will be understood as the claims and the equivalent concept to be described below.

What is claimed is:

1. A vertical ultraviolet light emitting device, comprising:
a p-type semiconductor layer including Al;
an active layer positioned over the p-type semiconductor layer and including Al;
an n-type semiconductor layer positioned over the active layer and including Al;
a metal contact layer positioned over the n-type semiconductor layer and doped with an n type dopant; and
a pad formed over the metal contact layer and being in contact with the metal contact layer,
wherein the metal contact layer has an Al content lower than or equal to that of the n-type semiconductor layer.

2. The vertical ultraviolet light emitting device of claim 1, wherein the Al content of the metal contact layer decreases in a direction from the n-type semiconductor layer toward the pad.

3. The vertical ultraviolet light emitting device of claim 2, wherein the metal contact layer contacts with the pad at least a portion of the metal contact layer that is free of Al.

4. The vertical ultraviolet light emitting device of claim 1, wherein the active layer has multi-quantum well structure having quantum barrier layers and a quantum barrier layer closest to the n-type semiconductor layer has a band gap wider than that of other quantum barrier layers.

5. The vertical ultraviolet light emitting device of claim 1, wherein the metal contact layer has a surface with roughness, and
the pad is formed on the surface with roughness.

6. The vertical ultraviolet light emitting device of claim 1, wherein the metal contact layer is formed over a portion of the n-type semiconductor layer.

7. The vertical ultraviolet light emitting device of claim 6, further comprising:
a reflecting layer interposed between the metal contact layer and the n-type semiconductor layer.

8. The vertical ultraviolet light emitting device of claim 7, wherein the reflecting layer includes a super-lattice layer including layers having different refractive indexes.

9. The vertical ultraviolet light emitting device of claim 7, wherein the reflecting layer includes a single layer having a refractive index lower than those of adjacent layers.

10. A method of manufacturing a vertical ultraviolet light emitting device, is comprising:
forming a metal contact layer doped with an n type dopant over a substrate;
forming an n-type semiconductor layer including Al over the metal contact layer;
forming an active layer including Al over the n-type semiconductor layer;
forming a p-type semiconductor layer including Al over the active layer;
separating the substrate from the metal contact layer; and
forming a pad over a surface of the metal contact layer from which the substrate is separated.

11. The method of claim 10, further comprising, before the forming the pad:
wet-etching the surface of the metal contact layer to form roughness,
wherein the pad is formed over the surface with roughness.

12. The method of claim 10, further comprising, after the forming the pad:
wet-etching the surface of the metal contact layer to form roughness.

13. The method of claim 10, further comprising:
wet-etching a portion of the surface of the metal contact layer to form roughness,
wherein the pad is formed in the remaining portion without roughness.

14. The method of claim 13, further comprising:
forming a reflecting layer between the metal contact layer and the n-type semiconductor layer.

15. The method of claim 14, wherein the forming the reflecting layer includes forming the reflecting layer with a distributed Bragg reflector (DBR) structure .

16. The method of claim 14, wherein the forming the reflecting layer includes forming a single layer having a refractive index lower than that of adjacent layers.

17. A vertical ultraviolet light emitting device, comprising:
an epitaxial layer including a p-type semiconductor layer, an n-type semiconductor layer, and an active layer disposed between the p-type semiconductor layer and the n-type semiconductor layer;
a metal contact layer formed over the epitaxial layer and having a varying Al content; and
a pad formed over the metal contact layer and contacting with the metal contact layer,
wherein the metal contact layer has relatively high Al content at a portion close to the epitaxial layer and releatively low Al content at another portion close to the pad.

18. The vertical ultraviolet light emitting device of claim 17, wherein the Al content increases in a direction from the pad to the epitaxial layer.

19. The vertical ultraviolet light emtting device of claim 17, wherein the metal contact layer is free of Al at a portion in contact with the pad.

20. The vertical ultraviolet light emtting device of claim 17, wherein the active layer has multi-quantum well structure having quantum barrier layers and a quantum barrier layer closest to the n-type semiconductor layer has a band gap wider than that of other quantum barrier layers.
